(19) United States
(12) Patent Application Publication
(10) Pub. No.: US 2004/0021136 A1
(43) Pub. Date: Feb. 5, 2004

(54) Luminescent material, luminescent element, and device

(76) Inventors: Mikiko Matsuo, Nara (JP); Tetsuya Satou, Kadoma-shi Osaka (JP); Hisanori Sugiura, Hirakata-shi Osaka (JP); Hitoshi Hisada, Toyonaka-shi Osaka (JP)

Correspondence Address: PARKHURST & WENDEL, L.L.P., 1421 PRINCE STREET, SUITE 210, ALEXANDRIA, VA, 22314-2805, US

(21) Appl. No.: 10/399,494

(22) PCT Filed: Oct. 17, 2001
(86) PCT No.: PCT/JP01/09180

(30) Foreign Application Priority Data
Oct. 17, 2000 (JP) 2000-316154

(51) Int. Cl. H01L 47/00

(52) U.S. Cl. 257/1

(57) ABSTRACT

A blue luminescent material with excellent thermal stability and long-term stability, a light-emitting element utilizing this material, and a device utilizing this light-emitting element are provided. In addition, the present invention provides a light-emitting element that has good color purity, does not reduce current efficiency in high luminance regions, and does not degrade lifetime characteristics. The luminescent material is a polynuclear metal complex compound having a pyrazabole structure.

### TECHNICAL FIELD

The present invention relates to luminescent materials, light-emitting elements, and devices utilizing such light-emitting elements.

### BACKGROUND ART

In organic electroluminescent elements, electric charges (holes and electrons) injected from two electrodes, an anode and a cathode, recombine in an emitter and thus excitons are formed, and then the formed excitons excite molecules of a luminescent material, whereby the molecules of the luminescent material emit light. The organic electroluminescent element is known as an injection-type light-emitting element and therefore can be driven at low voltages.

For the organic electroluminescent device, first, there was developed an element having a structure in which an organic thin film had a two-layer structure, including a thin film made of a hole transport material and a thin film made of an electron transport material, and luminescence was produced as a result of the recombination of holes and electrons injected from the respective electrodes into the organic thin film (Applied Physics Letters, 51, 1987, P. 913).

In addition, there was developed an element having a three-layer structure including a hole transport material, a luminescent material, and an electron transport material (Japanese Journal of Applied Physics, Vol. 27, No. 2, P. 269). There was also reported an element in which a fluorescent dye was doped in a light-emitting layer to increase the performance of the element (Journal of Applied Physics, 65, 1989, P. 3610, and Japanese Unexamined Patent Publication No. 63-264692). In these reports, there was provided an element in which a fluorescent dye, such as a coumarin derivative or DCM1, was doped in an organic light-emitting layer made of aluminumquinoline, and it was found that the emission color could be changed by appropriately selecting dyes. Further, the reports revealed that the luminescence efficiency was also enhanced as compared to the undoping case.

Organic compounds used as luminescent materials have, because of their diversity, an advantage in that theoretically the emission color can be changed to any color by changing the molecular structure. Therefore, it can be said that by conducting molecular design, three colors, R (red), G (green), and B (blue), with good color purity required for full color displays are easily obtained

Doping methods, in which fluorescent pigments or laser dyes are doped in a light-emitting layer as guest materials, are beneficial methods to increase luminescence efficiency and improve color purity. However, in the doping method, a guest material absorbs energy from a host material, thereby emitting light. The luminescence to be obtained is energetically low; that is, luminescence with long luminescence wavelengths can be obtained. In terms of this, the doping method is an effective method for obtaining light with long wavelengths such as green and red. On the other hand, for obtaining light with short wavelengths such as blue luminescence, the doping method has problems such as a reduction in color purity. In addition, the optimum doping concentration in the doping method is usually as low as 0.1% to 1%, and thus it is difficult to control concentration.

Blue luminescence is energetically high and therefore the stress acting on luminescent materials is high. For this reason, the luminescent materials degrade rapidly, causing a problem with durability.

Moreover, as luminescent materials that do not employ the doping method, there is a need for the development of materials that have both an electric charge transport function and a light-emitting function. However, with materials having been developed up to now, when fluorescent dyes are used at high concentrations, there arise problems such as a reduction in luminescent luminance, due to an association between the fluorescent dyes, or the like.

### DISCLOSURE OF THE INVENTION

In view of the foregoing and other problems, it is an object of the present invention to provide a blue luminescent material with excellent thermal stability and long-term stability, a light-emitting element utilizing such a material, and a device utilizing such a light-emitting element.

In addition, it is another object of the present invention to provide a light-emitting element that has good color purity, does not reduce current efficiency in high luminance regions, and does not degrade lifetime characteristics.

It is to be noted that aspects of the present invention are based on the same or similar ideas. However, respective aspects of the present invention are embodied by different examples.

(A) in the present invention, there were found novel blue luminescent materials with excellent thermal stability.

The luminescent materials of the present invention are polynuclear metal complex compounds having a plurality of boron atoms as the metal center. Boron atoms have a small atomic radius. Therefore, the boron atoms are strongly bound to ligands, thereby forming a complex compound which is very stable even to heat. In particular, even when vapor-depositing polynuclear metal complex compounds on a substrate at high temperatures, the polynuclear metal complex compounds of the present invention exist stably. Hence, the polynuclear metal complex compounds of the present invention are particularly desirable as luminescent materials for use in organic EL elements.

The present inventors have found that as a polynuclear metal complex compound having a plurality of boron atoms as the metal center, a polynuclear metal complex compound having a pyrazabole structure had excellent electron transport properties (Japanese Unexamined Patent Publication No. 2000-3044). The pyrazabole structure is such that conjugated electrons are delocalized and pyrazole rings with strong aromaticity and boron atoms are bonded together. By making nitrogen atoms serve as coordinating atoms that bind to the boron atoms, the pyrazole rings act as ligands that form a chelate compound with metal-chelate bonds having strong covalent bonding. Consequently, a stable polynuclear metal complex compound is obtained. In addition, polynuclear metal complex compounds such as pyrazabole, in many cases, adopt complex conformations. Thus, in many cases, the form of polynuclear metal complex compounds to be obtained turns out to be such that molecules assemble and aggregate together in various ways. Accordingly, the polynuclear metal complex compounds of the present invention are particularly desirable as constituent materials of organic EL elements that require amorphous properties.

For compounds having the pyrazabole structure that are used as electron transport materials, the compounds shown below, for example, are known.

A-1: Pyrazabole

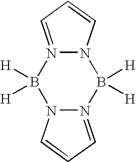

A-2: 1,3,5,7-tetramethylpyrazabole

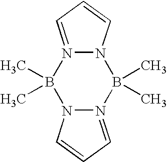

A-3: 4,4,8,8-tetraethylpyrazabole

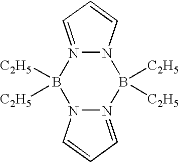

A-4: 4,4,8,8-tetrakis(1H-pyrazole-1-yl)pyrazabole

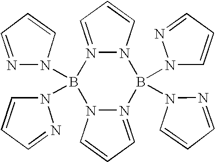

These pyrazabole structures exhibit purple luminescence caused by pyrazole rings. The luminescence of the pyrazabole structure is stable and strong. In general, a portion involved in luminescence in a molecule is the portion with which II electrons are conjugated. Ligands in polynuclear metal complex compounds include a bridging ligand that is coordinated so as to bridge a plurality of boron atoms, and a common ligand that is coordinated to one boron atom. In the pyrazabole structures of A-1 to A-3, the bridging ligand portion serves as the luminescent part. On the other hand, in the pyrazabole structure of A-4, both the bridging ligand and the ligand have n-conjugated electrons. The optical absorption and luminescence in organic molecules are primarily caused by an electron transition between the HOMO and LUMO. In order to examine whether an electron transition involved in the optical absorption and luminescent processes is occurred in either the bridging ligand or the ligand in the pyrazabole structure of A-4, a molecular orbital calculation was performed. In the pyrazabole structure of A-4, electrons were localized in the bridging ligand portion in both the HOMO and LUMO. From this result, it was found that the pyrazole ring, which is a bridging ligand, serves as the luminescent part.

The present inventors have investigated substituents that are to be introduced onto the pyrazole rings, which are bridging ligands; consequently, luminescent materials that produce stable and intense blue light were obtained. Specifically, the present invention is as follows:

The present invention provides a luminescent material comprising a polynuclear metal complex compound which is represented by the following general formula (1):

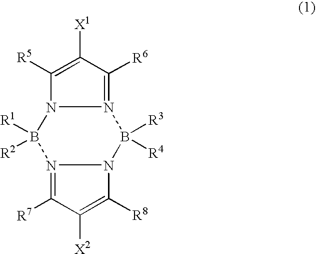

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;

R⁵, R⁶, R⁷, and R⁸ may be the same or different and are individually selected from the group consisting of hydrogen, an alkyl group with from 1 to 3 carbon atoms which may have a substituent, and an alkenyl group with 2 or 3 carbon atoms which may have a substituent; and

X¹ and X² may be the same or different and are individually selected from the group consisting of an aryl group which may have a substituent and a nitrogen-containing hetero ring group which may have a substituent.

Alternatively, there is provided a luminescent material comprising a polynuclear metal complex compound which is represented by the following general formula (2):

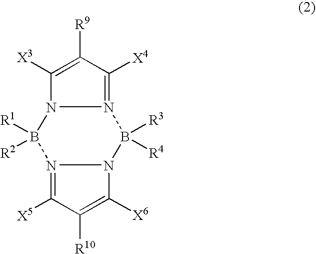

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;

R⁹ and R¹⁰ may be the same or different and are individually selected from the group consisting of hydrogen, an alkyl group with from 1 to 3 carbon atoms which may have a substituent, and an alkenyl group with 2 or 3 carbon atoms which may have a substituent; and

X³, X⁴, X⁶, and X⁶ may be the same or different and are individually selected from the group consisting of an aryl group which may have a substituent and a nitrogen-containing hetero ring group which may have a substituent.

There is provided a luminescent material comprising a polynuclear metal complex compound which is represented by the following general formula (3):

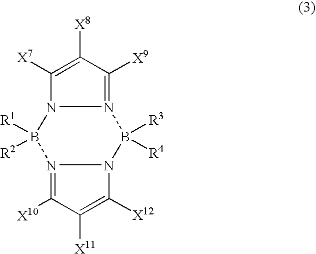

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring; and

X⁷, X⁸, X⁹, X¹⁰, X¹¹, and X¹² may be the same or different, are individually selected from the group consisting of a hydrogen atom, an alkyl group with from 1 to 3 carbon atoms which may have a substituent, and an alkenyl group with 2 or 3 carbon atoms which may have a substituent, and X⁷ and X⁸ and/or X⁸ and X⁹, or X¹⁰ and X¹¹ and/or X¹¹ and X¹² may individually or simultaneously be joined together to form an aromatic ring, and further the substituents may be joined together to form a ring.

In these configurations, groups having II electrons are introduced onto the pyrazole rings which are bridging ligands. As a result, the conjugation of the II electrons in the pyrazole rings extends to substituents, and therefore the polynuclear metal complex compounds of the present invention emit blue light. In addition, the polynuclear metal complex compounds of the present invention have the pyrazabole structure, and thus have excellent electron transport properties.

(B) There is provided a light-emitting element comprising an anode, a cathode, and a layer provided between the anode and the cathode, the layer having a light-emitting region, wherein the layer may comprise luminescent materials which are compounds represented by the foregoing general formulae (1) to (3).

When the layer having a light-emitting region contains luminescent materials which are compounds represented by the foregoing general formulae (1) to (3), light-emitting elements can be obtained which have good color purity and emit blue light.

The above-described light-emitting elements may comprise a cathode, an anode, and a hole transport layer and an electron transport layer stacked on top of each other between the cathode and the anode, wherein the electron transport layer may be the above-described layer having a light-emitting region.

In addition, the above-described light-emitting elements may comprise an anode, a cathode, and a light-emitting layer provided between the anode and the cathode, wherein the light-emitting layer may be the above-described layer having a light-emitting region.

With such configurations, it is possible to more effectively utilize the functions of the luminescent materials of the present invention having electron transport properties.

Devices using the above-described light-emitting elements can be configured as follows.

There is provided a display device comprising an image signal output portion for generating image signals, a driving portion for generating an electric current in accordance with the image signals generated by the image signal output portion, and a light-emitting portion for emitting light in accordance with the electric current generated by the driving portion, wherein the light-emitting portion includes at least one light-emitting element, the light-emitting element comprising an anode, a cathode, and a light-emitting layer provided between the anode and the cathode, the light-emitting layer containing any luminescent material described in the foregoing general formulae (1) to (3).

This display device may be such that a plurality of light-emitting elements are arranged in a matrix on a substrate.

This display device may be formed such that the light-emitting elements are stacked on a substrate having provided thereon thin film transistors for controlling the operation of the light-emitting elements.

There is provided a lighting device comprising a driving portion for generating an electric current and a light-emitting portion for emitting light in accordance with the electric current generated by the driving portion, wherein the light-emitting portion includes at least one light-emitting element, the light-emitting element comprising an anode, a cathode, and a light-emitting layer provided between the anode and the cathode, the light-emitting layer containing any luminescent material described in the foregoing general formulae (1) to (3).

### BRIEF DESCRIPTION OF THE DRAWINGS

FIG. 1 is a schematic view showing one embodiment of a light-emitting element of the present invention.

FIG. 2 is a schematic view illustrating one example of a display device using the light-emitting elements of the present invention.

FIG. 3 is a schematic view illustrating one example of a lighting device using the light-emitting element of the present invention.

### BEST MODE FOR CARRYING OUT THE INVENTION The present invention is described below with reference to the drawings.

### Embodiment 1

A luminescent material of the present invention is characterized in that the material is a polynuclear metal complex compound represented by the following general formula (1):

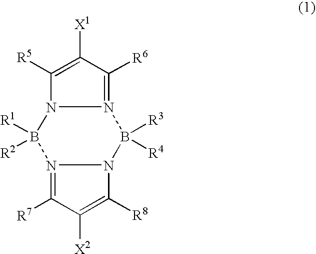

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;

R⁵, R⁶, R⁷, and R⁸ may be the same or different and are individually selected from the group consisting of hydrogen, an alkyl group with from 1 to 3 carbon atoms which may have a substituent, and an alkenyl group with 2 or 3 carbon atoms which may have a substituent; and

X¹ and X² may be the same or different and are individually selected from the group consisting of an aryl group which may have a substituent and a nitrogen-containing hetero ring group which may have a substituent.

The alkyl groups with from 1 to 5 carbon atoms represented by R¹, R², R³, and R⁴ may be linear, branched, or cyclic. Specific examples of alkyl groups include a methyl, an ethyl, a propyl, an isopropyl, a butyl, a tert-butyl, a pentyl, a cyclopropyl, a cyclopentyl group and the like.

The aryl groups, which may have a substituent, represented by R¹, R², R³, and R⁴ are preferably an aryl group with from 6 to 20 carbon atoms, and particularly preferably an aryl group with from 6 to 14 carbon atoms Specific examples of aryl groups include a phenyl, a 3-methylphenyl, a naphthyl group and the like.

The nitrogen-containing hetero ring groups, which may have a substituent, represented by R¹, R², R³, and R⁴ are preferably a five- to ten-membered ring aromatic hetero ring group containing at least one nitrogen atom, and particularly preferably a five- or six-membered ring aromatic hetero ring group. Specific examples of aromatic hetero rings include a ring having one nitrogen atom, such as pyrrole, pyridine, or oxazole, and a ring having two or more nitrogen atoms, such as imidazole, pyrazole, pyridazine, pyrazine, pyrimidine, oxadiazole, triazole, triazine, tetrazine, or tetrazole

These aryl and nitrogen-containing hetero ring groups may have a substituent. In the case where the aryl group or the nitrogen-containing hetero ring group has substituents, the substituents may be joined together to form a ring.

In the nitrogen-containing hetero ring group, in the case where a ring is formed by the substituents being joined together, a part of the ring may have another boron atom. Further, this ring may have a pyrazabole structure having boron atoms as the metal center. Specifically, in some cases, the luminescent material of the present invention may have two or more pyrazabole structures in one molecule.

Examples of the alkyl groups with from 1 to 3 carbon atoms represented by R⁵, R⁶, R⁷, and R⁸ include a methyl, an ethyl, a propyl, and an isopropyl group; preferably a methyl and an ethyl group. These alkyl groups may have a substituent. Examples of substituents include the aryl group which may have a substituent and nitrogen-containing hetero ring group which may have a substituent, which are used for the above R¹, R², R³, and R⁴.

Examples of the alkenyl groups with 2 or 3 carbon atoms, which may have a substituent, represented by R⁵, R⁶, R⁷, and R⁸ include a vinyl, a 1-propenyl, an allyl, and an isopropenyl group; preferably a vinyl group. These alkenyl groups may have a substituent. Examples of substituents include the aryl group which may have a substituent and nitrogen-containing hetero ring group which may have a substituent, which are used for the above R¹, R², R³, and R⁴.

Examples of the aryl groups which may have a substituent, alkylene groups which may have a substituent, and nitrogen-containing hetero ring groups which may have a substituent, represented by X¹ and X², include the aryl groups, alkylene groups, nitrogen-containing hetero ring aryl groups, and nitrogen-containing hetero ring groups which may have a substituent, represented by the above R¹, R², R³, and R⁴.

The aryl groups, which may have a substituent, represented by X¹ and X² are preferably an aryl group with from 6 to 20 carbon atoms, and particularly preferably an aryl group with from 6 to 14 carbon atoms. Specific examples of aryl groups include a phenyl, a naphthyl, and an anthryl group.

In the luminescent material of the present invention, the X groups play an important role in achieving blue luminescence. Specifically, II-electron conjugation extends from the pyrazole rings to the X groups, and thus the emission wavelength shifts to longer wavelengths. Accordingly, the luminescent material of the present invention emits a blue color.

In addition, in cases where substituents of the pyrazole rings, which are other than R¹, R², R³, and R⁴, are alkenyl groups, II electrons easily spread out from the pyrazole rings to the alkenyl groups, and therefore blue luminescence is easily obtained.

Another luminescent material of the present invention is characterized in that the material is a polynuclear metal complex compound represented by the following general formula (2):

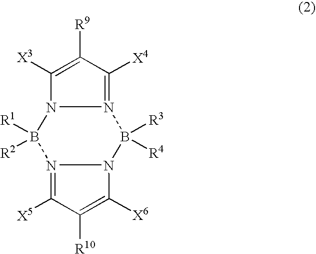

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;

R⁹ and R¹⁰ may be the same or different and are individually selected from the group consisting of hydrogen, an alkyl group with from 1 to 3 carbon atoms which may have a substituent, and an alkenyl group with 2 or 3 carbon atoms which may have a substituent; and

X³, X⁴, X⁵, and X⁶ may be the same or different and are individually selected from the group consisting of an aryl group which may have a substituent and a nitrogen-containing hetero ring group which may have a substituent.

R¹, R², R³, and R⁴ have the same meaning as given above.

R⁹ and R¹⁰ have the same meaning as the above R⁵, R⁶, R⁷, and R⁸.

X³, X⁴, X⁵, and X⁶ have the same meaning as the above X¹ and X².

A still another luminescent material of the present invention is characterized in that the material is a polynuclear metal complex compound represented by the following general formula (3):

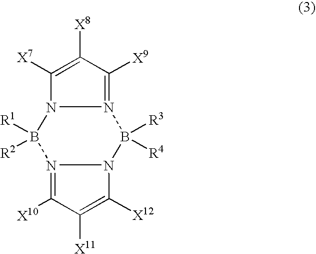

wherein R¹, R², R³, and R⁴ may be the same or different, are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring; and

X⁷, X⁸, X⁹, X¹⁰, X¹¹, and X¹² may be the same or different, are individually selected from the group consisting of a hydrogen atom, an alkyl group with from 1 to 3 carbon atoms which may have a substituent, and an alkylene group which may have a substituent, and X⁷ and X⁸ and/or X⁸ and X⁹, or X¹⁰ and X¹¹ and/or X¹¹ and X¹² may individually or simultaneously be joined together to form an aromatic ring, and further the substituents may be joined together to form an aromatic ring.

R¹, R², R³, and R⁴ have the same meaning as given above.

The alkyl or alkylene group for X⁷, X⁸, X⁹, X¹⁰, X¹¹, and X¹² have the same meaning as the alkyl or alkylene group for the above R⁵, R⁶, R⁷, and R⁸. The meaning of “X⁷ and X⁸ and/or X⁸ and X⁹, or X¹⁰ and X¹¹ and/or X¹¹ and X¹² may individually or simultaneously be joined together to form an aromatic ring” is that X⁷ and X⁸ and/or X⁸ and X⁹, or X¹⁰ and X¹¹ and/or X¹¹ and X¹² have a pyrazole ring and form a mono or bicyclic aromatic ring. Specifically, it means the formation of aromatic rings such as benzene and naphthalene rings.

The meaning of “the substituents may be joined together to form a ring” is that a mono or bicyclic aromatic ring having a pyrazole ring further has another condensed ring. A specific example of such a case would be the formation of rings, such as a phenalene, a phenanthrene, an anthracene, and a pyrene ring, that have the above-mentioned mono or bicyclic aromatic ring.

Specific examples of the above-described luminescent materials include those having, for example, the following structures.

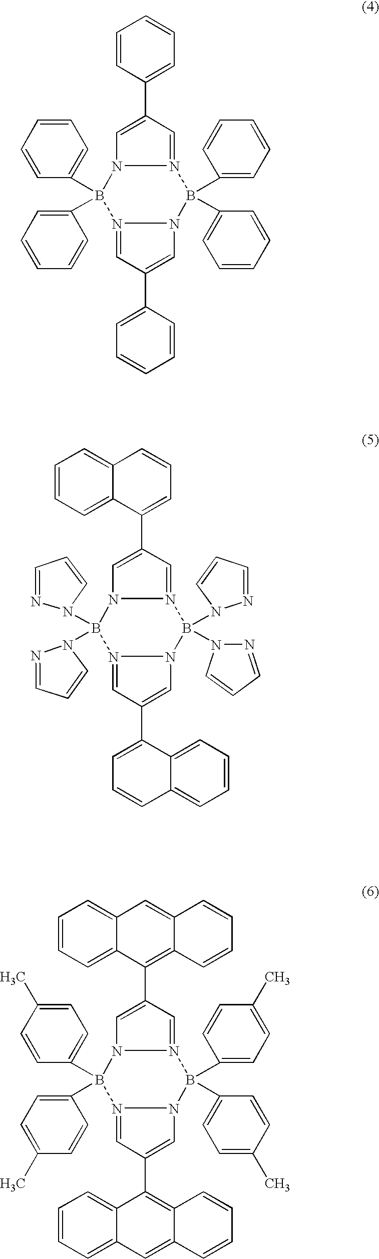

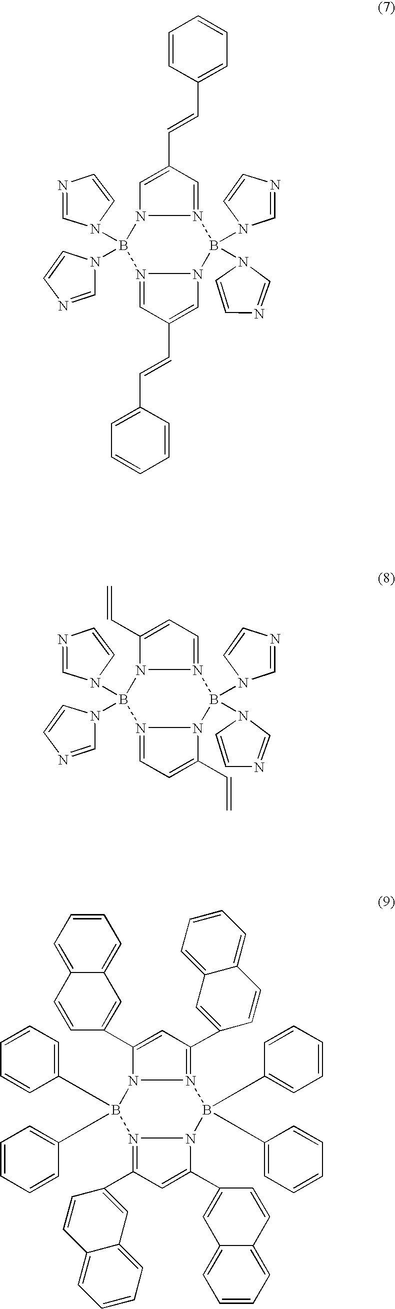

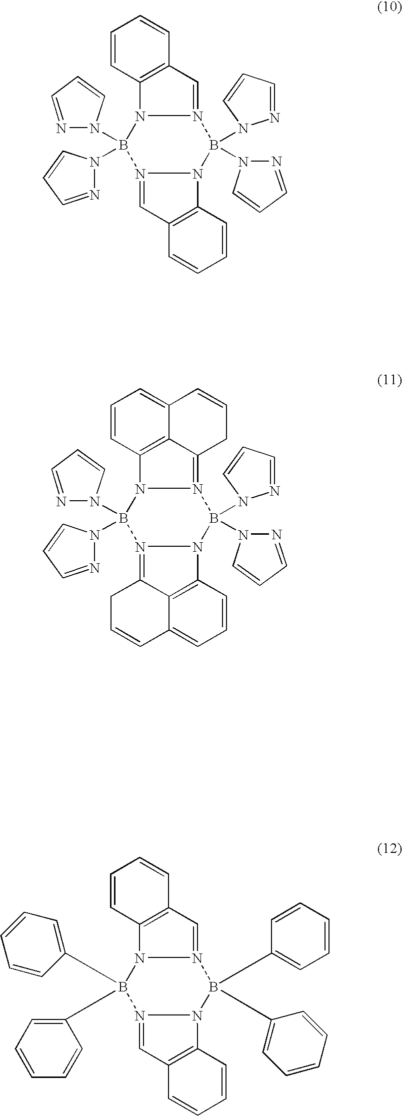

The light-emitting elements of the present invention are such that a layer having a light-emitting region is included between an anode and a cathode. The layer having a light-emitting region contains the above-described luminescent materials.

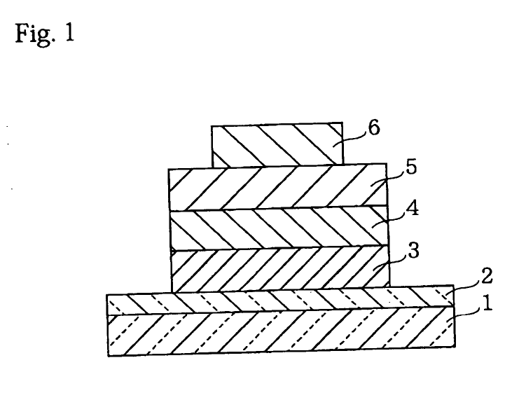

The light-emitting elements of the present invention may include, in addition to the layer having a light-emitting region, other functional layers. FIG. 1 is a schematic view showing one example of a light-emitting element that can be used in the present invention. For example, as shown in FIG. 1, the element may include, in sequence, an anode 2, a hole transport layer 3, a light-emitting layer 4, an electron transport layer 5, and a cathode 6 stacked on top of each other on a transparent substrate 1. This configuration is commonly referred to as a DH structure.

In addition to the above configuration, even when a light-emitting element has an SH-A structure in which the light-emitting layer 4 also functions as the electron transport layer 5, an SH-B structure in which the light-emitting layer 4 also functions as the hole transport layer 3, or a single layer structure in which the light-emitting layer 4 also functions as the hole transport layer 3 and the electron transport layer 5, the element can be used as the light-emitting element of the present invention. Since the luminescent materials of the present invention have electron transport properties, the SH-A structure is desirable.

As used herein, the “term light-emitting element” refers to an element having a functional layer(s), including at least a light-emitting layer, provided between a hole transport electrode and an electron-injecting electrode. The functional layer(s) may be formed of a layer(s) of organic material, or may include a layer of inorganic material. For example, the electron transport layer may be composed of a layer of inorganic material and the hole transport layer may be composed of a layer of organic material. Conversely, it is also possible that the electron transport layer may be composed of a layer of organic material and the hole transport layer may be composed of a layer of inorganic material. Alternatively, any one or more of the hole transport layer, light-emitting layer, and electron transport layer may be composed of a layer of inorganic material.

A light-emitting element having the structure shown in FIG. 1 can be fabricated, for example, in the following manner. The transparent substrate 1 is not particularly limited; any substrate can be used so long as the substrate has moderate strength, is not adversely affected by heat upon vapor deposition and the like when fabricating the element, and is transparent. Examples of materials for the transparent substrate 1 include glass (e.g., Corning 1737 and the like) and transparent resins such as polyethylene, polypropylene, polyethersulfone, polycarbonate, and polyether ether ketone. Not only the light-emitting element of the present embodiment, but also other light-emitting elements according to the present invention can be fabricated by sequentially stacking the layers on top of each other on the transparent substrate 1.

The anode 2 shown in the drawing is usually composed of a transparent conductive film, which applies to all the light-emitting elements of the present invention. For materials for such a transparent conductive film, it is desirable to use conductive substances having a work function higher than the order of 4 eV. Examples of such substances include conductive compounds such as carbon, metals, e.g., aluminum, vanadium, iron, cobalt, nickel, copper, zinc, tungsten, silver, tin, gold, etc., and alloys of these metals, and conductive metal compounds such as metal oxides, e.g., tin oxide, indium oxide, antimony oxide, zinc oxide, zirconium oxide, etc., and solid solutions or mixtures of these metal oxides (e.g., ITO (indium tin oxide) and the like).

The anode 2 can be formed on the transparent substrate 1 by vapor deposition, sputtering or the like, or by sol-gel method, using conductive substances such as those described above, or alternatively by a technique in which such conductive substances are dispersed in a resin or the like and the dispersion is applied to the substrate, so that desired translucency and electrical conductivity can be ensured. An ITO film, in particular, is deposited by sputtering, electron-beam deposition, ion plating or the like, for the purpose of improving the transparency of the film or lowering the resistivity of the film.

The thickness of the anode 2 is determined by the required sheet resistance and visible light transmittance. In the case of light-emitting elements, since the driving current density is comparatively high, the sheet resistance needs to be reduced. For this reason, the film thickness is 100 nm or more in most cases.

Next, on the anode 2, the hole transport layer 3 is formed. Any known material can be used as hole transport materials for use in forming the hole transport layer of the light-emitting elements of the present invention, including the hole transport layer 3 shown in the drawing; however, preferred materials are derivatives having, as the basic skeleton, triphenylamine with excellent luminescence stability and excellent durability.

Specific examples of hole transport materials include tetraphenylbenzidine compounds, triphenylamine trimers, and benzidine dimers as disclosed in Japanese Unexamined Patent Publication No. 7-126615, various tetraphenyldiamine derivatives as disclosed in Japanese Unexamined Patent Publication No. 8-48656, N,N′-diphenyl-N,N′-bis(3-methylphenyl)-1, 1′-biphenyl-4,4′-diamine MTPD (commonly referred to as TPD)) as disclosed in Japanese Unexamined Patent Publication No. 7-65958, and the like. Triphenylamine tetramers as disclosed in Japanese Unexamined Patent Publication No. 10-228982 are more preferable. In addition, diphenylamino-α-phenylstilbene, diphenylaminophenyl-α-phenylstilbene, and the like can also be used. Further, inorganic materials for forming p-layers, such as amorphous silicon, may be used.

The thickness of the hole transport layer 3 should be on the order of 10 nm to 1000 nm. When the thickness of the hole transport layer is less than 10 nm, though the luminescence efficiency is good, dielectric breakdown and the like easily occur, resulting in shortening of the lifetime of the element. On the other hand, when the thickness of the hole transport layer 3 exceeds more than 1000 nm, the applied voltage needs to be increased to produce luminescence with a given luminance, which in turn provides a poor luminescence efficiency and easily causes element degradation.

Subsequently, on the hole transport layer 3, the light-emitting layer 4 is formed. The light-emitting layer 4 of the light-emitting element shown in FIG. 1 contains the above-described luminescent materials.

The thickness of the light-emitting layer 4 should be on the order of 5 nm to 1000 nm. When the thickness of the light-emitting layer is less than 5 nm, though the luminescence efficiency is good, dielectric breakdown and the like easily occur, resulting in shortening of the lifetime of the element. On the other hand, when the thickness of the light-emitting layer exceeds more than 1000 nm, the applied voltage needs to be increased to produce luminescence with a given luminance, which in turn provides a poor luminescence efficiency and easily causes element degradation. Typically, the thickness should be on the order of 5 nm to 100 nm.

The light-emitting layer 4 may further include a hole transport material or an electron transport material, in addition to the above-described luminescent materials, for the purpose of improving charge transport properties. In addition, a luminescent material may be dispersed in a polymer matrix.

On the light-emitting layer 4, the electron transport layer. 5 is formed. Any known material can be used as electron transport materials for use in forming the electron transport layer of the light-emitting elements of the present invention, including the electron transport layer 5 shown in the drawing; a preferred material is tris(8-quinolinolato)aluminum (aluminumquinoline, hereinafter referred to as Alq). Examples of other electron transport materials include metal complexes such as tris(4-methyl-8-quinolinolato)aluminum, 3-(2′-benzothiazolyl)-7-diethylaminocoumarin, and the like.

The thickness of the electron transport layer 5 should be on the order of 10 nm to 1000 nm. When the thickness of the electron transport layer is less than 10 nm, though the luminescence efficiency is good, dielectric breakdown and the like easily occur, resulting in shortening of the lifetime of the element. On the other hand, when the thickness of the electron transport layer exceeds more than 1000 nm, the applied voltage needs to be increased to produce luminescence with a given luminance, which in turn provides a poor luminescence efficiency and easily causes element degradation.

The hole transport layer 3 and the electron transport layer 5 may each be composed of a single layer; however, in view of ionization potential and the like, those layers may each be composed of a plurality of layers.

The hole transport layer 3, the light-emitting layer 4, and the electron transport layer 5 may be formed by vapor deposition, or alternatively by coating methods, such as dip coating and spin coating, using a solution in which materials for forming such layers are dissolved, or using a solution in which materials for forming such layers are dissolved with suitable resins. The Langmuir-Blodgett (LB) method may also be employed. The preferred deposition is vacuum deposition. With the vacuum deposition, the above-described layers can be formed in an amorphous state and homogeneously. Since the luminescent materials of the present invention, in particular, are complex compounds that are very stable even to heat, and thus can exist stably even at high temperatures upon vapor deposition.

The hole transport layer 3, the light-emitting layer 4, and the electron transport layer 5 may be formed individually; however, it is desirable to form the layers successively in a vacuum. When the layers are formed successively, it is possible to prevent impurities from getting on the interfaces between the layers, preventing a reduction in operating voltage and improving characteristics, i.e., enhancement of the luminescence efficiency, increased lifetimes, and the like.

In cases where any of the hole transport layer 3, the light-emitting layer 4, and the electron transport layer 5 contains a plurality of compounds and the layers are formed by vacuum deposition, it is desirable to perform co-deposition with a plurality of boats, each containing a single compound, being individually subjected to temperature control; however, it is also possible to perform vapor deposition using a mixture in which a plurality of compounds are mixed in advance.

Although not shown in the drawing, an electron-injecting layer for improving the electron injection and transport properties may be formed on the electron transport layer 5. As electron injecting materials for forming the electron-injecting layer, various types of known electron injecting materials can be used; preferred materials are alkali metals (e.g., lithium, sodium, and the like), alkaline-earth metals (e.g., beryllium, magnesium, and the like), salts and oxides of these metals, and the like.

The electron-injecting layer can be formed by vapor deposition, sputtering, or the like. The thickness of the layer should be on the order of 0.1 nm to 20 nm.

Next, on the electron transport layer 5, the cathode 6 is formed. For the cathode of the light-emitting elements of the present invention, including the cathode 6 shown in FIG. 1, it is desirable to use alloys of low work function metals. In the case where the above-described electron-injecting layer is formed, it is also possible to stack on the electron-injecting layer a layer of high work function metals such as aluminum and silver. In addition, when the cathode is formed of transparent or translucent material, planar luminescence can be extracted from the cathode side.

The cathode 6 is formed by vapor deposition, sputtering or the like, using metal materials such as those described above. The thickness of the cathode is preferably in the range of 10 nm to 500 nm, and more preferably in the range of 50 nm to 500 nm, in terms of electrical conductivity and manufacturing stability.

The luminescent materials used in the light-emitting elements of the present invention contain a blue luminescent substance with high color purity. Hence, the white balance is improved, and thus high-grade display devices and high-grade lighting devices can be provided. The display device may be such that a plurality of the light-emitting elements of the present invention are arranged in a matrix on a substrate, or such that the light-emitting elements of the present invention are stacked on a substrate having provided thereon thin film transistors for controlling the operation of the light-emitting elements. The lighting device can create, as a novel light source with planar luminescence, new lighting space. In addition, the lighting device can be applied to other optical applications.

A method of synthesizing the compounds of the present invention is described in detail below.

### Synthesis Method 1

Synthesis of Compound (12)

Equal amounts of 1H-indazole and triphenylborane were dissolved in toluene and then reacted with heating to reflux until the generation of benzene has stopped. After pouring the reaction mixture into cold water, the precipitated solid was filtered. A mixture of the product and pyrazole with a mole equivalent four times that of the product was heated with stirring to desorb hydrogen. The reaction product was recrystallized in boiling toluene, thereby obtaining compound (12). The yield was 75%.

Synthesis of another polynuclear metal complex compound having different bridging ligands was also made possible by using pyrazole with a desired substituent instead of the above-described 1H-indazole. In addition, synthesis of still another polynuclear metal complex compound having different ligands was also made possible by using a compound with a desired skeleton instead of the above-described pyrazole with a mole equivalent four times that of the product.

### EXAMPLE 1

In this example, there is described one example of an element having the configuration shown in FIG. 1. On a glass substrate having deposited thereon ITO, a hole transport layer made of N,N′-bis(4-diphenylamino-4-biphenylyl)-N,N′-diphenylbenzidine with a thickness of 50 nm was formed. Next, a light-emitting layer was formed by vapor-depositing a material represented by the structural formula (4), to a thickness of 20 nm. Subsequently, an electron transport layer made of Alq with a thickness of 20 nm was formed. On the electron transport layer, lithium was vapor-deposited to 1 nm. Thereafter, a cathode made of aluminum with a thickness of 100 nm was formed. Thus, a light-emitting element shown in FIG. 1 was fabricated.

A direct current voltage was applied to the light-emitting element of the present example to evaluate the characteristics of the element. As a result, blue luminescence with a luminescence efficiency of 2.5 cd/A was obtained.

### EXAMPLE 2

A light-emitting element was fabricated in a manner similar to Example 1, except that a compound represented by the structural formula (5) was used as the luminescent material. When the light-emitting element was allowed to emit light by applying a direct current voltage thereto, blue luminescence with a luminescence efficiency of 2.9 cd/A was obtained.

### EXAMPLE 3

A light-emitting element was fabricated in a manner similar to Example 1, except that a compound represented by the structural formula (6) was used as the luminescent material. When the light-emitting element was allowed to emit light by applying a direct current voltage thereto, blue luminescence with a luminescence efficiency of 3.6 cd/A was obtained.

### EXAMPLE 4

A light-emitting element was fabricated in a manner similar to Example 1, except that a compound represented by the structural formula (7) was used as the luminescent material and the compound represented by the structural formula (7) and 20 wt % 4-N,N′-bis(p-methylphenyl)amino-α-phenylstilbene were co-deposited. When the light-emitting element was allowed to emit light by applying a direct current voltage thereto, blue luminescence with a luminescence efficiency of 3.5 cd/A was obtained.

### EXAMPLE 5

A light-emitting element was fabricated in a manner similar to Example 1, except that a compound represented by the structural formula (8) was used as the luminescent material. When the light-emitting element was allowed to emit light by applying a direct current voltage thereto, blue luminescence with a luminescence efficiency of 3.0 cd/A was obtained.

### EXAMPLE 6

A light-emitting element was fabricated in a manner similar to Example 1, except that a compound represented by the structural formula (9) was used as the luminescent material and the compound represented by the structural formula (9) and 30 wt % tristolylamine were co-deposited. When the light-emitting element was allowed to emit light by applying a direct current voltage thereto, blue luminescence with a luminescence efficiency of 2.8 cd/A was obtained.

### EXAMPLE 7

A light-emitting element was fabricated in a manner similar to Example 1, except that a compound represented by the structural formula (10) was used as the luminescent material. When the light-emitting element was allowed to emit light by applying a direct current voltage thereto, blue luminescence with a luminescence efficiency of 4.7 cd/A was obtained.

### EXAMPLE 8

A light-emitting element was fabricated in a manner similar to Example 1, except that a compound represented by the structural formula (11) was used as the luminescent material. When the light-emitting element was allowed to emit light by applying a direct current voltage thereto, blue luminescence with a luminescence efficiency of 2.8 cd/A was obtained

### EXAMPLE 9

A light-emitting element was fabricated in a manner similar to Example 1, except that a compound represented by the structural formula (12) was used as the luminescent material. When the light-emitting element was allowed to emit light by applying a direct current voltage thereto, blue luminescence with a luminescence efficiency of 4.5 cd/A was obtained.

### EXAMPLE 10

A constant-current luminescence test was performed on the light-emitting elements obtained in the foregoing examples at an initial luminance of 500 cd/m²; as a result, the light-emitting elements continued to emit light stably for over 1000 hours.

### EXAMPLE 11

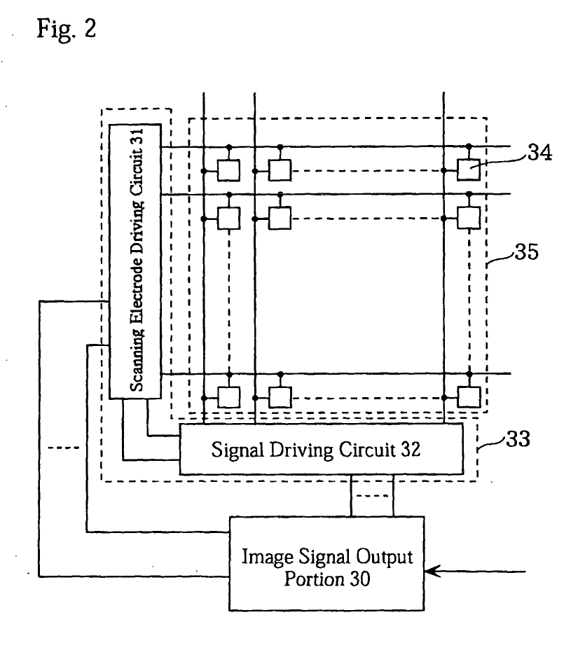

FIG. 2 is a schematic view illustrating one example of a display device using the light-emitting elements of the present invention. In this example, the display device includes an image signal output portion 30 for generating image signals, a driving portion 33 having a scanning electrode driving circuit 31 for outputting the image signals from the image signal output portion and a signal driving circuit 32, and a light-emitting portion 3.5 having light-emitting elements 34 arranged in a 100×100 matrix. Using the light-emitting elements fabricated in Examples 1 to 10, electroluminescent display devices having the configuration shown in FIG. 2 were fabricated in which respective elements were arranged in a 100×100 matrix. Then, the display devices were allowed to display moving images. In all the display devices, excellent images with high color purity were obtained. Many electroluminescent display devices were fabricated, but there were no variations between the display devices; devices with excellent in-plane uniformity were obtained.

### EXAMPLE 12

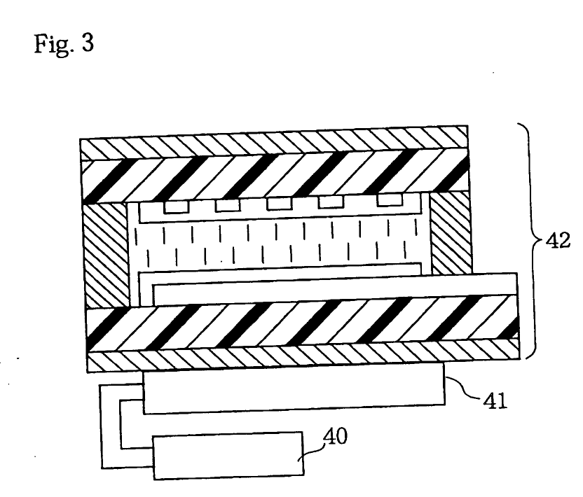

FIG. 3 is a schematic view illustrating one example of a lighting device using the light-emitting element of the present invention. In this example, the lighting device includes a driving portion 40 for generating an electric current and a light-emitting portion 41 having a light-emitting element that emits light in accordance with the electric current generated by the driving portion. In this example, the lighting device was used as the backlight for a liquid crystal display panel 42. Each of the light-emitting elements fabricated in Examples 1 to 10 was formed on a film substrate and then was allowed to emit light by applying a voltage thereto. As a result, lighting devices that produced curved, uniform, planar luminescence were obtained without the need to use indirect lighting which leads to loss of luminance.

### Industrial Applicability

As has been described above, the luminescent materials of the present invention are blue luminescent materials with excellent color purity and have excellent thermal stability and long-term stability.

Furthermore, the use of such luminescent materials in light-emitting elements makes it possible to provide light-emitting elements that have good color purity, do not reduce current efficiency in high luminance regions, and do not degrade lifetime characteristics.

Thus, the value of the present invention to industry is considerable.

What is claimed is:

1. A luminescent material comprising a polynuclear metal complex compound which is represented by the following general formula (1): 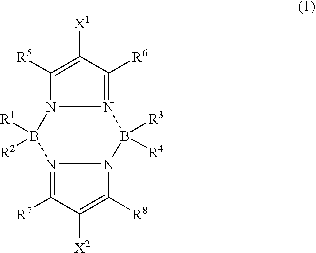
wherein R¹, R², R³, and R⁴ are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;
R⁵, R⁶, R⁷, and R⁸ are individually selected from the group consisting of hydrogen, an alkyl group with from 1 to 3 carbon atoms which may have a substituent, and an alkenyl group with 2 or 3 carbon atoms which may have a substituent; and X¹ and X² are individually selected from the group consisting of an aryl group which may have a substituent and a nitrogen-containing hetero ring group which may have a substituent.

2. A luminescent material comprising a polynuclear metal complex compound which is represented by the following general formula (2): 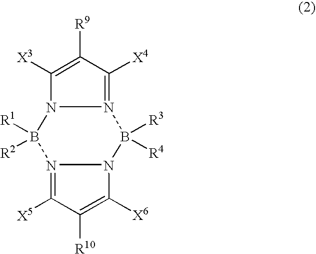
wherein R¹, R², R³, and R⁴ are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;
R⁹ and R¹⁰ are individually selected from the group consisting of hydrogen, an alkyl group with from 1 to 3 carbon atoms which may have a substituent, and an alkenyl group with 2 or 3 carbon atoms which may have a substituent; and X³, X⁴, X⁵, and X⁶ are individually selected from the group consisting of an aryl group which may have a substituent and a nitrogen-containing hetero ring group which may have a substituent.

3. A luminescent material comprising a polynuclear metal complex compound which is represented by the following general formula (3): 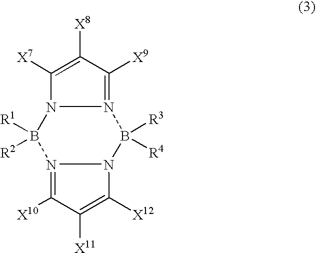
wherein R¹, R², R³, and R⁴ are individually selected from the group consisting of a hydrogen atom, an alkyl group with from 1 to 5 carbon atoms, an alkenyl group with 2 or 3 carbon atoms which may have a substituent, an aryl group which may have a substituent, and a nitrogen-containing hetero ring group which may have a substituent, and R¹ and R² and/or R³ and R⁴ may be joined together to form a ring; and
X⁷, X⁸, X⁹, X¹⁰, X¹¹, and X¹² are individually selected from the group consisting of a hydrogen atom, an alkyl group with from 1 to 3 carbon atoms which may have a substituent, and an alkenyl group with 2 or 3 carbon atoms which may have a substituent, and X⁷ and X⁸ and/or X⁸ and X⁹, or X¹⁰ and X¹¹ and/or X¹¹ and X¹² may individually or simultaneously be joined together to form an aromatic ring, and further the substituents may be joined together to form a ring.

4. A light-emitting element comprising an anode, a cathode, and a layer provided between the anode and the cathode, the layer having a light-emitting region, wherein the layer comprises a luminescent material which is a compound represented by the following general formula (1): 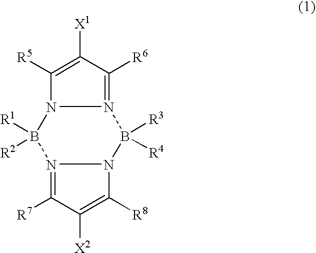
wherein R¹, R², R³, and R⁴ are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;
R⁵, R⁶, R⁷, and R⁸ are individually selected from the group consisting of hydrogen, an alkyl group with from 1 to 3 carbon atoms which may have a substituent, and an alkenyl group with 2 or 3 carbon atoms which may have a substituent; and
X¹ and X² are individually selected from the group consisting of an aryl group which may have a substituent, an alkylene group which may have a substituent, and a nitrogen-containing hetero ring group which may have a substituent.

5. A light-emitting element comprising an anode, a cathode, and a layer provided between the anode and the cathode, the layer having a light-emitting region, wherein the layer comprises a luminescent material which is a compound represented by the following general formula (2): 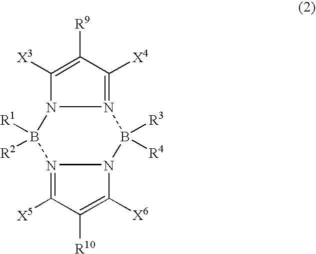
wherein R¹, R², R³, and R⁴ are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring;
R⁹ and R¹⁰ are individually selected from the group consisting of hydrogen, an alkyl group with from 1 to 3 carbon atoms which may have a substituent, and an alkenyl group with 2 or 3 carbon atoms which may have a substituent; and
X³, X⁴, X⁵, and X⁶ are individually selected from the group consisting of an aryl group which may have a substituent and a nitrogen-containing hetero ring group which may have a substituent.

6. A light-emitting element comprising an anode, a cathode, and a layer provided between the anode and the cathode, the layer having a light-emitting region, wherein the layer comprises a luminescent material which is a compound represented by the following general formula (3): 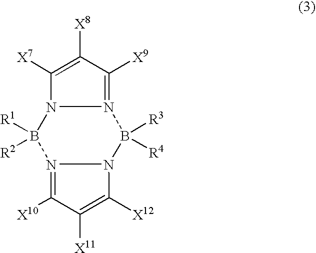
wherein R¹, R², R³, and R⁴ are individually selected from the group consisting of a hydrogen atom, an alkyl group with from 1 to 5 carbon atoms, an aryl group which may have a substituent, and a nitrogen-containing hetero ring group which may have a substituent, and R¹ and R² and/or R³ and R⁴ may be joined together to form a ring; and
X⁷, X⁸, X⁹, X¹⁰, X¹¹, and X¹² are individually selected from the group consisting of a hydrogen atom, an alkyl group with from 1 to 3 carbon atoms which may have a substituent, and an alkenyl group with 2 or 3 carbon atoms which may have a substituent, and X⁷ and X⁸ and/or X⁸ and X⁹, or X¹⁰ and X¹¹ and/or X¹¹ and X¹² may individually or simultaneously be joined together to form an aromatic ring, and further the substituents may be joined together to form a ring.

7. Alight-emitting element comprising a cathode, an anode, and a hole transport layer and an electron transport layer stacked on top of each other between the cathode and the anode, wherein the electron transport layer is the layer having a light-emitting region according to any one of claims 4 to 6.

8. A light-emitting element comprising an anode, a cathode, and a light-emitting layer provided between the anode and the cathode, wherein the light-emitting layer is the layer having a light-emitting region according to any one of claims 4 to 6.

9. A display device comprising an image signal output portion for generating image signals, a driving portion for generating an electric current in accordance with the image signals generated by the image signal output portion, and a light-emitting portion for emitting light in accordance with the electric current generated by the driving portion, wherein
the light-emitting portion includes at least one light-emitting element, the light-emitting element comprising an anode, a cathode, and a light-emitting layer provided between the anode and the cathode, the light-emitting layer containing a luminescent material according to any one of claims 1 to 3.

10. A lighting device comprising a driving portion for generating an electric current and a light-emitting portion for emitting light in accordance with the electric current generated by the driving portion, wherein
the light-emitting portion includes at least one light-emitting element, the light-emitting element comprising an anode, a cathode, and a light-emitting layer provided between the anode and the cathode, the light-emitting layer containing a luminescent material according to any one of claims 1 to 3.
